(19) United States
(12) Patent Application Publication
(10) Pub. No.: US 2025/0270483 A1
(43) Pub. Date: Aug. 28, 2025

(54) CLEANING COMPOSITION AND METHOD OF FORMING PHOTORESIST PATTERN USING THE SAME

(71) Applicant: DONGWOO FINE-CHEM CO., LTD., Jeollabuk-do (KR)

(72) Inventors: JI MIN CHUN, Jeollabuk-do (KR); SO MIN LEE, Jeollabuk-do (KR); TAE KYUNG LEE, Jeollabuk-do (KR); YONG HWAN CHO, Jeollabuk-do (KR)

(21) Appl. No.: 19/038,850

(22) Filed: Jan. 28, 2025

(30) Foreign Application Priority Data
Feb. 22, 2024 (KR) 10-2024-0025720

(51) Int. Cl. C11D 7/50; C11D 7/26; G03F 7/42

(52) U.S. Cl. CPC C11D 7/5022; C11D 7/266; G03F 7/422; C11D 2111/22

(57) ABSTRACT

A cleaning composition includes an alkanol having 1 to 6 carbon atoms, an acetate compound and water. A content of water may be 50 wt % to 95 wt % based on a total weight of the cleaning composition. In a method of forming a photoresist pattern, a photoresist film is formed on a substrate, the photoresist film is partially removed to form a photoresist pattern, and the substrate on which the photoresist pattern is formed is cleaned using the cleaning composition.

### CROSS REFERENCE TO RELATED APPLICATION AND CLAIM OF PRIORITY

This application claims the benefit under 35 USC § 119 of Korean Patent Application No. 10-2024-0025720 filed on Feb. 22, 2024 in the Korean Intellectual Property Office, the entire disclosure of which is incorporated herein by reference for all purposes.

### BACKGROUND

### 1. Field of the Invention

The present invention relates to a cleaning composition and a method of forming a photoresist pattern using the same.

### 2. Description of the Related Art

Photoresist is a chemical film which is capable of forming a fine pattern drawn in advance on a photomask on a desired substrate using a photochemical reaction by light. A polymer material applied to an exposure technique along with the photomask is recognized as a major factor which directly affects a degree of integration and determines an ultimate resolution limit of a device. In order to put the increasing integration of circuits into a semiconductor with a limited size, it is necessary to pattern the designed circuits smaller. Due to the increase in the degree of integration of the semiconductor, development of new photoresist is inevitably required.

In order to manufacture a semiconductor device or a high-resolution flat panel display, a photolithography process for forming a fine line on a substrate using the photoresist is generally used. The photolithography process is a method of applying photoresist to the substrate using thermal, mechanical and chemical properties of the photoresist, then exposing the substrate to light with a predetermined wavelength, followed by performing dry or wet etching thereon.

In a fine patterning technique using the photoresist, a field that is becoming important along with the development of new photoresists is a cleaning composition for a semiconductor substrate. After forming a photoresist pattern by exposure and development processes, residues remaining on the semiconductor substrate should be removed by a cleaning composition.

Cleaning using the cleaning composition may include, for example, removing the remaining photoresist film by spraying distilled water from an upper portion of a spin device while spinning the semiconductor substrate. However, in this case, due to a high surface tension of distilled water, the pattern may be collapsed.

Therefore, a cleaning composition which has an excellent removal power against the residues generated after the exposure and development processes, and can improve line width roughness (LWR) of the pattern, as well as prevent collapse of the pattern is required.

Korean Patent No. 10-1376340 discloses a composition for cleaning a semiconductor substrate.

### SUMMARY

An object of the present invention is to provide a cleaning composition capable of preventing collapse of a pattern and improving line width roughness.

Another object of the present invention is to provide a method of forming a photoresist pattern using the cleaning composition.

To achieve the above objects, the following technical solutions are adopted in the present invention.

1. A cleaning composition including: an alkanol having 1 to 6 carbon atoms; an acetate compound; and water, wherein a content of water based on a total weight of the cleaning composition is 50% by weight to 95% by weight.

2. The cleaning composition according to the above 1, wherein the alkanol has a boiling point (T_{b}) of 60° C. to 160° C.

3. The cleaning composition according to the above 1, wherein the alkanol has a Hansen solubility parameter (δH) of 31 MPa^{0.5} to 41 MPa^{0.5}.

4. The cleaning composition according to the above 1, the alkanol has a Hansen solubility parameter distance in water of 1.5 MPa^{0.5} to 12 MPa^{0.5}.

5. The cleaning composition according to the above 1, wherein the alkanol is a monohydric alkanol.

6. The cleaning composition according to the above 1, wherein the alkanol includes an alkyl group having 3 to 5 carbon atoms.

7. The cleaning composition according to the above 6, wherein the alkanol includes at least one selected from the group consisting of 1-propanol, 2-propanol, 1-butanol, 2-butanol, iso-butanol, 2-methyl-2-propanol, 1-pentanol, 2-pentanol, 3-pentanol, and 3-methyl-1-butanol.

8. The cleaning composition according to the above 1, wherein a content of the alkanol is 3% by weight to 35% by weight based on the total weight of the cleaning composition.

9. The cleaning composition according to the above 1, wherein the acetate compound includes an alkyl group having 2 to 6 carbon atoms.

10. The cleaning composition according to the above 9, wherein the acetate compound includes a branched alkyl group.

11. The cleaning composition according to the above 1, wherein the acetate compound includes at least one selected from the group consisting of n-propyl acetate, n-butyl acetate, sec-butyl acetate, and tert-butyl acetate.

12. The cleaning composition according to the above 1, wherein a content of the acetate compound is 0.001% by weight to 1.5% by weight based on the total weight of the cleaning composition.

13. The cleaning composition according to the above 1, wherein the content of water is 65% by weight to 95% by weight based on the total weight of the cleaning composition.

14. A method of forming a photoresist pattern including: forming a photoresist film on a substrate; partially removing the photoresist film to form a photoresist pattern; and cleaning the substrate on which the photoresist pattern is formed using the cleaning composition according to the above 1.

The cleaning composition according to exemplary embodiments of the present invention may suppress deformation of a pattern (e.g., a photoresist pattern) while having an improved cleaning power against foreign substances.

The cleaning composition may have a low surface tension against a photoresist film. When the cleaning composition has a high surface tension, a pattern having a high aspect ratio may be collapsed as the cleaning composition evaporates. However, the cleaning composition may include alcohol, such that the surface tension may be decreased. Accordingly, collapse of a fine pattern of a photoresist film due to the high surface tension may be suppressed.

In addition, the cleaning composition may have high solubility against a photoresist film, for example. Accordingly, by cleaning the photoresist film with the cleaning composition, the line width roughness of the pattern formed on the photoresist film may be reduced, and a removal efficiency of residues that may exist on the photoresist film may be improved.

The cleaning composition according to exemplary embodiments of the present invention may be used to form a pattern of a photoresist film. Accordingly, reliability in the formation of pattern may be improved.

### BRIEF DESCRIPTION OF THE DRAWINGS

The above and other objects, features and other advantages of the present invention will be more clearly understood from the following detailed description taken in conjunction with the accompanying drawings, in which:

FIGS. 1 to 4 are schematic cross-sectional views for describing a method of forming a pattern according to exemplary embodiments.

### DETAILED DESCRIPTION

According to exemplary embodiments of the present invention, a cleaning composition which includes an alkanol, an acetate compound and water is provided. In addition, a method of forming a photoresist pattern using the cleaning composition is provided.

Hereinafter, embodiments of the present invention will be described in detail.

The cleaning composition according to exemplary embodiments may include an alkanol having 1 to 6 carbon atoms, an acetate compound and water.

The term “alkanol” as used herein refers to a compound having a saturated hydrocarbon group and a hydroxy group. For example, the alkanol may refer to an alcohol which does not include an additional functional group (e.g., an ether group, etc.) other than the hydroxy group.

For example, the term “alkanol” as used herein is not limited to the valance, order or series of alcohols, if it does not include the additional functional group. For example, the alkanol may be used to refer to all alcohols such as monohydric, dihydric and trihydric alcohols. For example, the alkanol may be used to refer to primary, secondary and tertiary alcohols, or Class 1, Class 2 and Class 3 alcohols.

The cleaning composition may remove, for example, process residues such as undeveloped photoresist or residual developer existing on a semiconductor substrate. For example, organic/inorganic residues existing between photoresist patterns after exposure and development may be dissolved in the cleaning composition including the alkanol, thus to effectively remove the residues from the photoresist patterns.

In addition, since the cleaning composition includes the acetate compound, it is possible to reduce line width roughness (LWR) while minimizing damage to the structure of a semiconductor device such as a photoresist pattern.

According to exemplary embodiments, the alkanol of the cleaning composition may have an alkyl group having 1 to 6 carbon atoms. When the number of carbon atoms of the alkyl group included in the alkanol exceeds 6, damage to the photoresist film may occur due to a length of alkanol molecules, and the solubility in water may be decreased.

Since the number of carbon atoms of the alkyl group included in the alkanol is 1 to 6, the solubility in water may be high. In addition, the alkanol may be dissolved in water to weaken a hydrogen bond between water molecules. Accordingly, the surface tension of the cleaning composition including the alkanol may be decreased. Therefore, collapse of the photoresist pattern due to high surface tension may be prevented.

In some embodiments, the alkanol may have a boiling point (T_{b}) of 60° C. to 160° C., 70° C. to 160° C., or 80° C. to 160° C. Within the above range, the alkanol may not evaporate during forming the photoresist pattern. In addition, due to high stress between the alkanols, it is possible to suppress them from being not dissolved in water or causing collapse of the photoresist pattern.

In some embodiments, the alkanol may have a Hansen solubility parameter (δ_{H}) of 31 MPa^{0.5} to 41 MPa^{0.5}, 31 MPa^{0.5} to 37 MPa^{0.5}, or 32 MPa^{0.5} to 37 MPa^{0.5}.

The Hansen solubility parameter is a parameter for the solubility of a specific substance determined by considering a dispersion force, a dipole-dipole force, and a hydrogen bonding force of the specific substance together, which may be expressed by Equation 1 below.

$${δ}_{H} = \sqrt{{δ}_{d}^{2} + {δ}_{p}^{2} + {δ}_{h}^{2}} \qquad [ Equation 1 ]$$

In Equation 1 above, δ_{H} means the Hansen solubility parameter (MPa^{0.5}), δ_{d} means a solubility parameter (MPa^{0.5}) due to the dispersion force, δₚ means a solubility parameter (MPa^{0.5}) due to the dipole-dipole force, and δₕ means a solubility parameter (MPa^{0.5}) due to the hydrogen bonding force.

For example, the Hansen solubility parameter (δ_{H}) of the alkanol calculated according to Equation 1 above may be within the above-described range.

Within the above range, an interaction force between alkanol molecules may be appropriately maintained. Accordingly, when cleaning the photoresist pattern, residues may be sufficiently removed without causing collapse of the photoresist pattern.

In some embodiments, the alkanol may have a Hansen solubility parameter distance in water of 1.5 MPa^{0.5} to 12 MPa^{0.5}, 2 MPa^{0.5} to 8 MPa^{0.5}, or 2 MPa^{0.5} to 4.5 MPa^{0.5}.

The term “Hansen solubility parameter distance” as used herein means a distance in the Hansen space of two compounds. For example, a “Hansen solubility parameter distance of A to B” means the distance in the Hansen space of A and B. For example, the “Hansen solubility parameter distance” may be calculated through Equation 2 below.

$${δ}_{H , d} = \sqrt{{( {δ}_{d , A} - {δ}_{d , B} )}^{2} + {( {δ}_{p , A} - {δ}_{p , B} )}^{2} + {( {δ}_{h , A} - {δ}_{h , B} )}^{2}} \qquad [ Equation 2 ]$$

In Equation 2 above, δ_{H,d} means the Hansen solubility parameter distance (MPa^{0.5}), δ_{d,A} and δ_{d,B} mean solubility parameters (MPa^{0.5}) due to dispersion forces of compounds A and B, respectively, δ_{p,A} and δ_{p,B} mean solubility parameters (MPa^{0.5}) due to dipole-dipole forces of the compounds A and B, respectively, and δ_{h,A} and δ_{h,A} mean solubility parameters (MPa^{0.5}) due to hydrogen bonding forces of the compounds A and B, respectively.

Within the above range, the alkanol may weaken the surface tension of water while being sufficiently dissolved in the water. Accordingly, when forming a photoresist pattern, the residues may be sufficiently removed while suppressing the collapse of the photoresist pattern.

In some embodiments, the alkanol may be a monohydric alkanol. Accordingly, it is possible to suppress the photoresist pattern, rather than the residues, from being dissolved due to an increase in the solubility of the photoresist in alkanol caused by the increase in the hydroxy group.

The term “monohydric alkanol” as used herein refers to an alcohol formed by bonding a hydroxy group to only one carbon atom among the carbon atoms of an alkyl group.

In some embodiments, the alkanol may include a branched alkyl group. Accordingly, damage to the photoresist pattern may be more suppressed by the alkyl group.

In some embodiments, the alkanol may include an alkyl group having 3 to 5 carbon atoms or an alkyl group having 3 to 4 carbon atoms. Accordingly, the alkanol may be dissolved in water to appropriately reduce the surface tension of the cleaning composition.

For example, when the number of carbon atoms of the alkyl group is 3 or more, the surface tension of the cleaning composition may be reduced to an appropriate level. Accordingly, the cleaning power of the cleaning composition may be further increased.

For example, when the number of carbon atoms of the alkyl group is 4 or less, the surface tension of the cleaning composition may be sufficiently reduced. Accordingly, damage to the photoresist pattern which may occur during cleaning may be further suppressed.

In one embodiment, the alkanol may include at least one selected from the group consisting of 1-propanol, 2-propanol, 1-butanol, 2-butanol, iso-butanol, 2-methyl-2-propanol, 1-pentanol, 2-pentanol, 3-pentanol, and 3-methyl-1-butanol. Accordingly, for example, only residues remaining on the photoresist pattern may be removed, thereby reducing the line width roughness and suppressing a decrease in the thickness or collapse of the photoresist pattern. Therefore, reliability in formation of the photoresist pattern may be improved.

For example, the alkanol may include at least one selected from the group consisting of 1-propanol, 1-butanol, 2-butanol, iso-butanol, and 1-pentanol. Accordingly, the reliability in formation of photoresist pattern may be further improved.

In some embodiments, the alkanol may be Class 1 or Class 2 alkanol, or primary or secondary alkanol. Accordingly, the alkanol may be dissolved in water to reduce the surface tension of the water. Accordingly, it is possible to suppress the collapse of the photoresist pattern.

The term “Class 1 alkanol” or “primary alkanol” as used herein refers to an alcohol in which a carbon atom to which a hydroxy group is bonded among the carbon atoms included in an alkyl group is bonded to two hydrogen atoms. For example, the primary alkanol may refer to an alcohol in which the hydroxy group is bonded to a carbon atom located at a terminal among the carbon atoms included in the alkyl group.

The term “Class 2 alkanol” or “secondary alkanol” as used herein refers to an alcohol in which a carbon atom in an alkyl group to which a hydroxy group is bonded is bonded to another carbon atom. For example, the secondary alkanol may refer to an alcohol in which the hydroxy group is bonded to a carbon atom directly bonded to another carbon atom located at the terminal of the alkyl group.

In some embodiments, the alkanol may not include a polyhydric alkanol. For example, the alkanol may substantially include only a monohydric alkanol.

For example, the solubility of the photoresist film in the polyhydric alkanol may be high. Therefore, when the polyhydric alkanol is included together, the photoresist film may be partially removed. When the polyhydric alkanol is not included, only residues of the photoresist pattern may be removed, such that the line width roughness may be further reduced.

In some embodiments, a content of the alkanol may be 3% by weight (“wt %”) to 35 w^{t}%, 5 wt % to 35 wt %, 5 wt % to 30 wt %, 10 wt % to 30 wt %, or 20 wt % to 30 wt % based on a total weight of the cleaning composition. Within the above content range, the solubility of the photoresist in the cleaning composition may be improved while reducing the surface tension of water. Accordingly, the residues may be effectively removed.

According to exemplary embodiments, the cleaning composition may include an acetate compound. The acetate compound may improve the solubility of the photoresist, for example, through an unshared electron pair included in the acetate compound. Accordingly, by cleaning the photoresist pattern with the cleaning composition, the line width roughness of the pattern may be improved, and the residues may be effectively removed.

In some embodiments, the acetate compound may include an alkyl group having 2 to 6, 3 to 6, or 3 to 4 carbon atoms. As the cleaning composition includes an acetate compound having the number of carbon atoms in the above range, the cleaning power for the residues may be improved, and the collapse of the photoresist pattern may be suppressed.

In one embodiment, the acetate compound may include a branched alkyl group. Accordingly, the cleaning power of the cleaning composition may be further improved and cleaning reliability may be enhanced.

In some embodiments, the acetate compound may include at least one selected from the group consisting of n-propyl acetate, n-butyl acetate, sec-butyl acetate, and tert-butyl acetate. Accordingly, the collapse of the photoresist pattern may be suppressed while improving the cleaning power for the residues.

For example, the acetate compound may include at least one of n-propyl acetate and secondary butyl acetate. Accordingly, the cleaning power of the cleaning composition may be further improved.

In some embodiments, the acetate compound may be at least two of the above-described acetate compounds. Accordingly, the surface tension of the cleaning composition may be further reduced, thereby suppressing the collapse of the pattern.

In some embodiments, a content of the acetate compound may be 0.001 wt % to 1.5 wt %, 0.001 wt % to 1 wt %, 0.001 wt % to 0.5 wt %, 0.01 wt % to 0.5 wt %, or 0.05 wt % to 0.5 wt % based on the total weight of the cleaning composition. Within the above content range, the line width roughness may be reduced while suppressing the collapse of the photoresist pattern during forming the photoresist pattern. In addition, the cleaning power of the cleaning composition may be improved.

The cleaning composition may include a solvent as an extra or balance. The term term “extra” or “balance” as used herein may refer to a variable amount which varies depending on addition of a component or formulation. For example, the balance may mean the remaining amount except for the above-described alkanol and acetate compound, or the remaining amount except for the alkanol, acetate compound and other additives. As the solvent, water may be used.

For example, the water may be deionized water for a semiconductor process, and deionized water having a resistivity of 18 MQ/cm or more may be used. When using the deionized water, process costs may be reduced, handling and wastewater treatment may be facilitated, and excellent cleaning power may also be achieved.

According to exemplary embodiments, a content of the water is 50 wt % to 95 wt % based on the total weight of the cleaning composition.

When the content of the water is less than 50 wt % based on the total weight of the cleaning composition, the solubility of the photoresist in the cleaning composition may be reduced. Accordingly, the cleaning power of the cleaning composition may be decreased.

When the content of the water is greater than 95 wt % based on the total weight of the cleaning composition, the contents of the alkanol and acetate included in the cleaning composition may be reduced excessively. Accordingly, the surface tension of the cleaning composition may be increased excessively, and the photoresist pattern may be collapsed.

When the water is included in the cleaning composition within the content range, the solubility in the photoresist may be increased while the surface tension is weakened. Accordingly, the reliability of the photoresist pattern and performance of removing the residues may be improved.

In some embodiments, the content of water may be 63 wt % to 97 wt %, 64 wt % to 95 wt %, 69 wt % to 95 wt %, 69.5 wt % to 90 wt %, 69.5 wt % to 80 wt %, or 69.5 wt % to 79.95 wt % based on the total weight of the cleaning composition. Within the above content range, the surface tension of the cleaning composition through the alkanol and acetate may be decreased, while the solubility of the photoresist in the cleaning composition is increased. Accordingly, the cleaning power and cleaning reliability of the cleaning composition may be improved.

FIGS. 1 to 4 are schematic cross-sectional views for describing a pattern forming method according to exemplary embodiments. For example, FIGS. 1 to 4 illustrate a pattern forming process using a negative photoresist.

However, the cleaning composition according to exemplary embodiments is not limited to the process shown in FIGS. 1 to 4, and may also be utilized in a pattern forming process using a positive photoresist.

Referring to FIG. 1, a photoresist material may be coated on a substrate 100 to form a photoresist film 110.

The substrate 100 may include a semiconductor material such as single crystal silicon or single crystal germanium, and may also be formed to include polysilicon.

In some embodiments, a soft baking process may be performed after forming the photoresist film 110. Accordingly, an organic solvent that can be included in the photoresist film 110 may be evaporated.

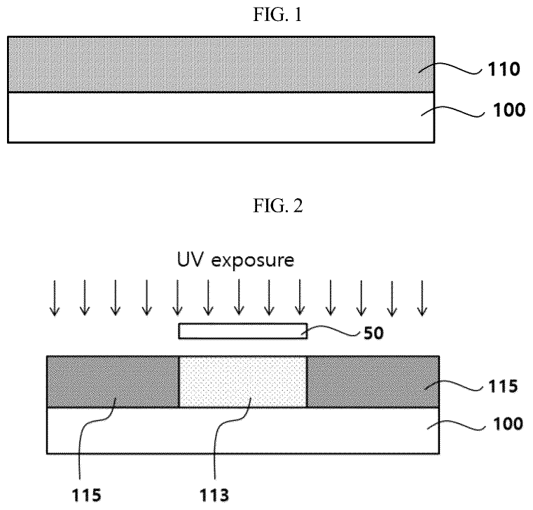

Referring to FIG. 2, a non-exposed part 113 and an exposed part 115 may be formed on the substrate 100 through an exposure process. The exposure process may be performed using a light source (e.g., an extreme ultraviolet (EUV) light source) and an exposure mask 50.

Light (e.g., EUV) passing through the exposure mask 50 may be irradiated onto the photoresist film 110. Thereby, the photoresist film 110 may have the non-exposed part 113 and the exposed part 115.

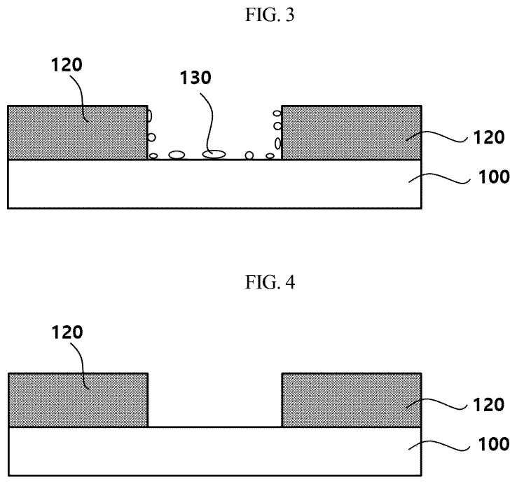

Referring to FIG. 3, a photoresist pattern 120 may be formed on the substrate 100 through a development process. For example, a developer may be used to remove the non-exposed part 113 on the substrate 100 to form the photoresist pattern 120 composed of the exposed part 115. The developer may be a tetramethylammonium hydroxide (TMAH) aqueous solution.

FIG. 3 illustrates a pattern forming process using a negative photoresist, but it is not limited thereto. For example, a pattern forming process using a positive photoresist may be performed, in this case, the exposed part 115 may be removed and a photoresist pattern composed of the non-exposed part 113 may be formed.

In some embodiments, a post-baking process may be further performed after the exposure process or after the development process.

After the formation process, a development residue 130 may exist on the substrate 100. The development residue 130 may be an undeveloped photoresist or a developer residue. As the development residue 130 remains on the substrate 100 or the photoresist pattern 120, a seam may be induced in the photoresist pattern 120, and the line width roughness of the pattern may be increased.

Referring to FIG. 4, the cleaning composition according to the above-described exemplary embodiments may be applied to or immersed on the substrate 100. Accordingly, the development residue 130 formed on the substrate 100 or the photoresist pattern 120 may be removed.

The cleaning step may be performed by applying the cleaning composition according to the above-described exemplary embodiments to the substrate 100 under cleaning conditions commonly known in the art.

In some embodiments, the temperature during cleaning may be 25° C. to 70° C., or 25° C. to 50° C. The residence time of the substrate 100 when immersed in the cleaning composition may be about 5 seconds to 10 minutes, or 10 seconds to 5 minutes.

In some embodiments, the cleaning step may be performed by performing a first cleaning using deionized water to remove the development residues, followed by a second cleaning using the cleaning composition according to the above-described exemplary embodiments.

As described above, as the cleaning composition includes the monoalcohol solvent and the polyhydric alcohol compound, undeveloped photoresist may be removed and a profile of the photoresist pattern 115 may be improved.

In addition, as the cleaning composition includes an alkanol having 1 to 6 carbon atoms, the surface tension thereof is reduced, such that only the development residue 130 may be effectively removed without causing a damage to a structure (e.g., the photoresist patterns) included in the semiconductor device.

Accordingly, photoresist scum, and pattern collapse, etc. that occur during the formation of the fine pattern may be prevented, thereby improving the line width roughness of the pattern, and may be usefully used in the formation of a fine pattern using an extreme ultraviolet lithography (EUVL) technique.

Hereinafter, embodiments of the present invention will be further described with reference to specific experimental examples. However, the following examples and comparative examples included in the experimental examples are only given for illustrating the present invention and those skilled in the art will obviously understand that various alterations and modifications are possible within the scope and spirit of the present invention. Such alterations and modifications are duly included in the appended claims.

### Examples and Comparative Examples

Cleaning compositions of Examples 1 to 31 and Comparative Examples 1 to 13 were prepared by mixing the components proposed in Table 1 (Examples) and Table 2 (Comparative Examples) in their respective contents. The content of each component was represented in units of wt % based on the total weight of the cleaning composition.

The Hansen solubility parameter (δ_{H}) and the Hansen solubility parameter distance (δ_{H,d}) of alkanol included in the cleaning composition were calculated through Equations 1 and 2 below, respectively.

$${δ}_{H} = \sqrt{{δ}_{d}^{2} + {δ}_{p}^{2} + {δ}_{h}^{2}} \qquad [ Equation 1 ]$$

In Equation 1 above, δ_{H} is the Hansen solubility parameter (MPa^{0.5}), δ_{d} is a solubility parameter (MPa^{0.5}) due to the dispersion force, δₚ is a solubility parameter (MPa^{0.5}) due to the dipole-dipole force, and δₕ is a solubility parameter (MPa^{0.5}) due to the hydrogen bonding force.

$${δ}_{H , d} = \sqrt{{( {δ}_{d , A} - {δ}_{d , B} )}^{2} + {( {δ}_{p , A} - {δ}_{p , B} )}^{2} + {( {δ}_{h , A} - {δ}_{h , B} )}^{2}} \qquad [ Equation 2 ]$$

In Equation 2 above, δ_{H,d} is the Hansen solubility parameter distance (MPa^{0.5}), δ_{d,A} and δ_{d,B} are solubility parameters (MPa^{0.5}) due to dispersion forces of alkanol and water, respectively, δ_{p,A} and δ_{p,B} are solubility parameters (MPa^{0.5}) due to dipole-dipole forces of the alkanol and water, respectively, and δ_{h,A} and δ_{lA} are solubility parameters (MPa^{0.5}) due to hydrogen bonding forces of the alkanol and water, respectively.

TABLE 1

| | Organic | Acetate | | | |
|---|---|---|---|---|---|
| | solvent | compound | Water | δ_{H} | δ_{H, d} |
| Item | (wt %) | (wt %) | (wt %) | (MPa^{0.5}) | (MPa^{0.5}) |
| Example 1 | 5 | 0.1 | 94.9 | 40.5 | 1.9 |
| | (A-1) | (B-2) | | | |
| Example 2 | 3 | 0.1 | 96.9 | 41.2 | 1.4 |
| | (A-1) | (B-2) | | | |
| Example 3 | 10 | 0.1 | 89.9 | 38.9 | 3.7 |
| | (A-1) | (B-2) | | | |
| Example 4 | 20 | 0.1 | 79.9 | 35.6 | 7.1 |
| | (A-1) | (B-2) | | | |
| Example 5 | 30 | 0.1 | 69.9 | 32.5 | 10.4 |
| | (A-1) | (B-2) | | | |
| Example 6 | 35 | 0.1 | 64.9 | 31.1 | 12.0 |
| | (A-1) | (B-2) | | | |
| Example 7 | 15 | 0.001 | 84.999 | 37.5 | 5.4 |
| | (A-1) | (B-1) | | | |
| Example 8 | 15 | 0.01 | 84.99 | 37.3 | 5.4 |
| | (A-1) | (B-1) | | | |
| Example 9 | 15 | 0.1 | 84.9 | 37.2 | 5.4 |
| | (A-1) | (B-1) | | | |
| Example 10 | 15 | 0.5 | 84.5 | 37.1 | 5.5 |
| | (A-1) | (B-1) | | | |
| Example 11 | 15 | 1 | 84 | 36.9 | 5.8 |
| | (A-1) | (B-1) | | | |
| Example 12 | 15 | 1.5 | 83.5 | 36.7 | 5.7 |
| | (A-1) | (B-1) | | | |
| Example 13 | 15 | 0.01 | 84.99 | 37.7 | 4.9 |
| | (A-3) | (B-2) | | | |
| Example 14 | 15 | 0.1 | 84.9 | 37.4 | 5.2 |
| | (A-3) | (B-2) | | | |
| Example 15 | 15 | 1 | 84 | 37.5 | 5.2 |
| | (A-3) | (B-2) | | | |
| Example 16 | 15 | 0.1 | 84.9 | 37.7 | 4.9 |
| | (A-2) | (B-1) | | | |
| Example 17 | 15 | 0.1 | 84.9 | 37.2 | 5.4 |
| | (A-3) | (B-1) | | | |
| Example 18 | 15 | 0.1 | 84.9 | 37.4 | 5.2 |
| | (A-4) | (B-1) | | | |
| Example 19 | 15 | 0.1 | 84.9 | 37.2 | 5.4 |
| | (A-5) | (B-1) | | | |
| Example 20 | 15 | 0.1 | 84.9 | 37.5 | 5.1 |
| | (A-1) | (B-2) | | | |
| Example 21 | 7.5/7.5 | 0.1 | 84.9 | 37.5 | 5.1 |
| | (A-1/A-3) | (B-1) | | | |
| Example 22 | 7.5/7.5 | 0.1 | 84.9 | 37.2 | 5.5 |
| | (A-1/A-3) | (B-2) | | | |
| Example 23 | 15 | 0.1/0.1 | 84.8 | 39.2 | 3.3 |
| | (A-1) | (B-1/B-2) | | | |
| Example 24 | 15 | 0.1 | 84.9 | 39.2 | 3.3 |
| | (A-10) | (B-1) | | | |
| Example 25 | 15 | 0.1 | 84.9 | 40.4 | 2.1 |
| | (A-10) | (B-2) | | | |
| Example 26 | 15 | 0.1 | 84.9 | 38.2 | 5.1 |
| | (A-11) | (B-1) | | | |
| Example 27 | 15 | 0.1 | 84.9 | 40.4 | 2.1 |
| | (A-11) | (B-2) | | | |
| Example 28 | 15 | 0.1 | 84.9 | 37.2 | 5.4 |
| | (A-12) | (B-1) | | | |
| Example 29 | 7.5/7.5 | 0.1 | 84.9 | 38.2 | 4.4 |
| | (A-1/A-10) | (B-1) | | | |
| Example 30 | 7.5/7.5 | 0.1 | 84.9 | 38.7 | 3.8 |
| | (A-1/A-11) | (B-1) | | | |
| Example 31 | 15 | 0.1 | 84.9 | 37.2 | 5.4 |
| | (A-1) | (B-3) | | | |

TABLE 2

| | Organic | Acetate | | | |
|---|---|---|---|---|---|
| | solvent | compound | Water | δ_{H} | δ_{H, d} |
| Item | (wt %) | (wt %) | (wt %) | (MPa^{0.5}) | (MPa^{0.5}) |
| Comparative | — | — | 100 | 42.3 | 0 |
| Example 1 | | | | | |
| Comparative | 15 | 0.1 | 84.9 | 36.7 | 5.9 |
| Example 2 | (A-6) | (B-1) | | | |
| Comparative | 15 | 0.1 | 84.9 | 38.3 | 4.1 |
| Example 3 | (A-7) | (B-1) | | | |
| Comparative | 15 | 0.1 | 84.9 | 37.3 | 5.2 |
| Example 4 | (A-8) | (B-1) | | | |
| Comparative | 15 | 0.1 | 84.9 | 37.3 | 5.1 |
| Example 5 | (A-9) | (B-1) | | | |
| Comparative | — | 0.1 | 99.9 | 42.3 | 0.0 |
| Example 6 | | (B-1) | | | |
| Comparative | — | 1.5 | 98.5 | 41.7 | 0.6 |
| Example 7 | | (B-1) | | | |
| Comparative | — | 0.1 | 99.9 | 42.3 | 0.0 |
| Example 8 | | (B-2) | | | |
| Comparative | — | 1.5 | 98.5 | 41.7 | 0.6 |
| Example 9 | | (B-2) | | | |
| Comparative | 15 | — | 85 | 37.3 | 5.4 |
| Example 10 | (A-1) | | | | |
| Comparative | 15 | — | 85 | 37.2 | 5.4 |
| Example 11 | (A-4) | | | | |
| Comparative | 15 | 0.1 | 84.9 | 36.7 | 5.9 |
| Example 12 | (A-6) | (B-2) | | | |
| Comparative | 7.5/7.5 | 0.1 | 84.9 | 37.3 | 5.3 |
| Example 13 | (A-1/A-8) | (B-2) | | | |

The components described in Tables 1 and 2 above are as follows.

### (A) Organic Solvent

A-1: 2-butanol
A-2: 1-butanol
A-3: 1-propanol
A-4: 1-pentanol
A-5: Iso-butanol
A-6: 1-Octanol
A-7: N-Methylformamide
A-8: Propylene glycol methyl ether
A-9: Dimethyl sulfoxide
A-10: Propylene glycol
A-11: Glycerin
A-12: 2-methyl-2-propanol

### (B) Acetate Compound

B-1: n-propyl acetate
B-2: sec-butyl acetate
B-3: n-butyl acetate

### Experimental Example

A lower antireflective film (DUV42P-6, Nissan Chemical Industries) was spin-coated on a silicon wafer, and then heated at 215° C. for 90 seconds to form a film having a thickness of 600 Å. A PHS-type photoresist (KTF-5664, Dongwoo Finechem) was spin-coated on an upper portion of the silicon wafer on which the film was formed to prepare a photoresist thin film, and then soft-baked in an oven at 100° C. for 60 seconds. Subsequently, the film was exposed using scanner equipment equipped with a KrF laser and post-baked in an oven at 110° C. for 60 seconds. Then, development was performed by immersing the film in a 2.38 wt % tetramethylammonium hydroxide (TMAH) aqueous solution for 60 seconds.

Thereafter, development residues on the upper portion of the silicon wafer was removed using deionized water. 30 ml of the cleaning composition of each of the examples was applied to the surface of the washed silicon wafer for 10 seconds, and then dried by high-speed spinning to obtain a pattern with a 180 nm line and space (IUS) resolution.

### (1) Evaluation of Pattern Collapse

Collapse phenomenon of the photoresist pattern was observed using CD-SEM (Critical Dimension Scanning Electron Microscope, Hitachi). Standards for evaluation thereof are as follows.

### <Standards for Evaluation>

∘: Pattern collapse does not occur
Δ: Collapse phenomenon occurs only in an edge pattern
x: Collapse phenomenon occurs in the edge and central patterns

### (2) Evaluation of Line Width Roughness

A line width roughness value was confirmed by measuring a difference between the widest portion and the narrowest portion of the photoresist pattern using the CD-SEM (Hitachi). It means that the smaller line width roughness value, the more uniform pattern.

### (3) Evaluation of Photoresist Pattern Damage

A difference in the photoresist thickness before and after treatment with the photoresist cleaning composition was measured using FE-SEM (Field-Emission Scanning Electron Microscope, Hitachi), and the degree of photoresist thickness reduction was confirmed. It means that the smaller difference in the photoresist thickness, the less photoresist pattern is damaged. Standards for evaluation thereof are as follows.

### <Standards for Evaluation>

∘: Difference in the photoresist thickness is 20 Å or less
Δ: Difference in the photoresist thickness is greater than 20 Å and 50 Å or less
x: Difference in the photoresist thickness is greater than 50 Å

### (4) Evaluation of Surface Tension

Surface tensions of the cleaning compositions according to the examples and comparative examples were measured using a K100 (KRUSS) Force Tensiometer as a surface tension meter.

Evaluation results are shown in Table 3 below.

TABLE 3

| | | Line width | | Surface |
|---|---|---|---|---|
| | Pattern | roughness | Pattern | tension |
| | collapse | (nm) | damage | (dyn/cm) |
| Example 1 | ◯ | 2.9 | ◯ | 32.5 |
| Example 2 | Δ | 2.9 | ◯ | 33.4 |
| Example 3 | ◯ | 2.8 | ◯ | 31.2 |
| Example 4 | ◯ | 2.7 | ◯ | 30.1 |
| Example 5 | ◯ | 2.8 | ◯ | 28.4 |
| Example 6 | ◯ | 2.8 | Δ | 27.2 |
| Example 7 | ◯ | 2.9 | ◯ | 29.6 |
| Example 8 | ◯ | 2.9 | ◯ | 29.4 |
| Example 9 | ◯ | 2.8 | ◯ | 29.7 |
| Example 10 | ◯ | 2.7 | ◯ | 29.6 |
| Example 11 | ◯ | 2.8 | ◯ | 29.5 |
| Example 12 | ◯ | 2.9 | Δ | 29.4 |
| Example 13 | ◯ | 2.9 | ◯ | 29.9 |
| Example 14 | ◯ | 2.8 | ◯ | 30.1 |
| Example 15 | ◯ | 2.9 | Δ | 29.8 |
| Example 16 | ◯ | 3.1 | ◯ | 30.2 |
| Example 17 | ◯ | 3.2 | ◯ | 31.4 |
| Example 18 | ◯ | 2.9 | ◯ | 29.4 |
| Example 19 | ◯ | 3 | ◯ | 28.9 |
| Example 20 | ◯ | 3.1 | ◯ | 30.1 |
| Example 21 | ◯ | 2.9 | Δ | 29.4 |
| Example 22 | ◯ | 2.9 | Δ | 30.1 |
| Example 23 | ◯ | 2.8 | ◯ | 29.7 |
| Example 24 | Δ | 3.2 | Δ | 33.4 |
| Example 25 | Δ | 3.2 | Δ | 34.4 |
| Example 26 | Δ | 3.1 | ◯ | 33.4 |
| Example 27 | Δ | 3.1 | ◯ | 33.7 |
| Example 28 | ◯ | 2.8 | ◯ | 29.7 |
| Example 29 | ◯ | 3.0 | ◯ | 30.2 |
| Example 30 | ◯ | 3.1 | ◯ | 30.1 |
| Example 31 | ◯ | 3.1 | ◯ | 33.7 |
| Comparative | X | 5 | ◯ | 72.5 |
| Example 1 | | | | |

| | |
|---|---|
| Comparative | Not dissolved |

| | | | | |
|---|---|---|---|---|
| Example 2 | | | | |
| Comparative | Δ | 4.2 | Δ | 31 |
| Example 3 | | | | |
| Comparative | ◯ | 4.3 | X | 58 |
| Example 4 | | | | |
| Comparative | Δ | 4.8 | X | 45 |
| Example 5 | | | | |
| Comparative | X | 4.7 | ◯ | 62 |
| Example 6 | | | | |
| Comparative | X | 5.2 | ◯ | 47 |
| Example 7 | | | | |
| Comparative | X | 4.5 | ◯ | 57 |
| Example 8 | | | | |
| Comparative | X | 5.2 | ◯ | 48 |
| Example 9 | | | | |
| Comparative | Δ | 4.5 | ◯ | 29.2 |
| Example 10 | | | | |
| Comparative | X | 5 | ◯ | 28.1 |
| Example 11 | | | | |

| | |
|---|---|
| Comparative | Not dissolved |

| | | | | |
|---|---|---|---|---|
| Example 12 | | | | |
| Comparative | Δ | 3.8 | Δ | 47 |
| Example 13 | | | | |

Referring to Table 3 above, in the examples using the cleaning composition which includes an alkanol including an alkyl group having 1 to 6 carbon atoms as an organic solvent, an acetate compound and water, the pattern collapse and pattern damage were reduced, and the line width roughness and surface tension were reduced.

In Example 2, where the content of the alkanol as an organic solvent was 3 wt % based on the total weight of the cleaning composition, the pattern collapse and surface tension were slightly increased.

In Example 6, where the content of alkanol as the organic solvent was 35 wt % based on the total weight of the cleaning composition, the pattern damage was slightly increased.

In Example 7, where the content of the acetate compound was 0.001 wt % based on the total weight of the cleaning composition, the line width roughness was slightly increased compared to Example 10, where the content of the acetate compound was 0.5 wt % based on the total weight of the cleaning composition.

In Example 12, where the content of the acetate compound was 1.5 wt % based on the total weight of the cleaning composition, the pattern damage was slightly increased.

In Example 14, where secondary butyl acetate was used as the acetate compound included in the cleaning composition, the line width roughness and surface tension were slightly reduced compared to Example 17, where n-propyl acetate was used as the acetate compound.

In Example 15, where the content of the acetate compound was 1 wt % based on the total weight of the cleaning composition, the pattern damage was slightly increased.

In Examples 21 and 22, where two types of alkanols were used together, the pattern collapse and surface tension were slightly reduced, but the pattern damage was slightly increased.

In Example 23, where two types of acetate compounds were used together, the surface tension was slightly reduced.

In Examples 24 to 27, where dihydric alkanol or trihydric alkanol was used, the line width roughness, pattern damage and surface tension were slightly increased.

In Example 28, where a tertiary alkanol was used, the line width roughness and surface tension were slightly reduced.

In Examples 29 and 30, where a monohydric alkanol and a polyhydric alkanol were used together, the line width roughness was slightly increased, but the surface tension was slightly decreased.

In Example 31, where an acetate compound including a linear alkyl group was used, the surface tension was slightly increased compared to Example 20, where an acetate compound including a branched alkyl group having the same number of carbon atoms was used.

In Comparative Example 1, where only water was used as the cleaning composition, the pattern collapse was increased, and the line width roughness and surface tension were increased.

In Comparative Examples 2 and 12, where 1-octanol was used as the organic solvent in the cleaning composition, the organic solvent was not dissolved in water, such that the cleaning composition was not formed.

In Comparative Examples 3 to 5, where the alkanol including an alkyl group having 1 to 6 carbon atoms was not used as the organic solvent included in the cleaning composition, the pattern collapse and pattern damage was increased, and the line width roughness and surface tension were increased.

In Comparative Examples 6 to 9, where the organic solvent in the cleaning composition was not used, the pattern collapse was increased, and the line width roughness and surface tension were increased.

In Comparative Examples 10 and 11, which did not include the acetate compound in the cleaning composition, the line width roughness and surface tension were increased.

In Comparative Example 13, where a hydroxy group-containing compound, not the alkanol, was used together with the alkanol having 1 to 6 carbon atoms as the organic solvent, the line width roughness, pattern damage, and surface tension were increased compared to the examples, where only the alkanol having 1 to 6 carbon atoms was used as the organic solvent.

What is claimed is:

1. A cleaning composition comprising:
an alkanol having 1 to 6 carbon atoms;
an acetate compound; and
water,
wherein a content of water based on a total weight of the cleaning composition is 50% by weight to 95% by weight.

2. The cleaning composition according to claim 1, wherein the alkanol has a boiling point (T_{b}) of 60° C. to 160° C.

3. The cleaning composition according to claim 1, wherein the alkanol has a Hansen solubility parameter (δH) of 31 MPa^{0.5} to 41 MPa^{0.5}.

4. The cleaning composition according to claim 1, the alkanol has a Hansen solubility parameter distance in water of 1.5 MPa^{0.5} to 12 MPa^{0.5}.

5. The cleaning composition according to claim 1, wherein the alkanol is a monohydric alkanol.

6. The cleaning composition according to claim 1, wherein the alkanol comprises an alkyl group having 3 to 5 carbon atoms.

7. The cleaning composition according to claim 6, wherein the alkanol comprises at least one selected from the group consisting of 1-propanol, 2-propanol, 1-butanol, 2-butanol, iso-butanol, 2-methyl-2-propanol, 1-pentanol, 2-pentanol, 3-pentanol, and 3-methyl-1-butanol.

8. The cleaning composition according to claim 1, wherein a content of the alkanol is 3% by weight to 35% by weight based on the total weight of the cleaning composition.

9. The cleaning composition according to claim 1, wherein the acetate compound comprises an alkyl group having 2 to 6 carbon atoms.

10. The cleaning composition according to claim 9, wherein the acetate compound comprises a branched alkyl group.

11. The cleaning composition according to claim 1, wherein the acetate compound comprises at least one selected from the group consisting of n-propyl acetate, n-butyl acetate, sec-butyl acetate, and tert-butyl acetate.

12. The cleaning composition according to claim 1, wherein a content of the acetate compound is 0.001% by weight to 1.5% by weight based on the total weight of the cleaning composition.

13. The cleaning composition according to claim 1, wherein the content of water is 65% by weight to 95% by weight based on the total weight of the cleaning composition.

14. A method of forming a photoresist pattern comprising:
forming a photoresist film on a substrate;
partially removing the photoresist film to form a photoresist pattern; and
cleaning the substrate on which the photoresist pattern is formed using the cleaning composition according to claim 1.
